(19) United States
(12) Patent Application Publication
(10) Pub. No.: US 2018/0057944 A1
(43) Pub. Date: Mar. 1, 2018

(54) MULTILAYER METAL MATRIX COMPOSITE AND FABRICATION THEREOF

(71) Applicants: Nader Mohammadian, Isfahan (IR); Ali Mahtab, Isfahan (IR); Seyed Amir Hosein Emami, Isfahan (IR); Kamran Amini, Isfahan (IR); Fereidoun Payami, Isfahan (IR); Mohammad Hosein Bina, Isfahan (IR)

(72) Inventors: Nader Mohammadian, Isfahan (IR); Ali Mahtab, Isfahan (IR); Seyed Amir Hosein Emami, Isfahan (IR); Kamran Amini, Isfahan (IR); Fereidoun Payami, Isfahan (IR); Mohammad Hosein Bina, Isfahan (IR)

(73) Assignees: Nader Mohammadian, Isfahan (IR); Ali Mahtab, Isfahan (IR); Islamic Azad University of Najafabad, Isfahan (IR)

(21) Appl. No.: 15/715,099

(22) Filed: Sep. 25, 2017

Related U.S. Application Data
(60) Provisional application No. 62/403,078, filed on Oct. 1, 2016.

(51) Int. Cl. C23C 18/32; C23C 18/16; C23C 14/14; C23C 16/06; C23C 4/126

(52) U.S. Cl. CPC C23C 18/32; C23C 18/1692; C23C 4/126; C23C 16/06; C23C 14/14

(57) ABSTRACT

A multilayer metal-matrix composite that includes a metal core sheet and a plurality of side sheets is disclosed in which the metal core sheet is reinforced with a reinforcement material selected from the group consisting of ceramic reinforcements. The reinforced metal core sheet is coated with an electroless coating. A method of fabricating a multilayer metal-matrix composite with reinforced particles and a coating using a combination of electroless coating method and accumulative roll bonding method is further described in this disclosure with the aim of reducing the number of required accumulative roll bonding cycles to obtain improved or desired properties.

### CROSS-REFERENCE TO RELATED APPLICATION

This application claims the benefit of priority from pending U.S. Provisional Patent Application Ser. No. 62/403,078, filed on Oct. 1, 2016, and entitled “A FABRICATION METHOD FOR NANOSTRUCTURED COMPOSITE SHEETS WITH ELECTROLESS COMPOSITE COATING VIA ACCUMULATIVE ROLL BONDING,” which is incorporated herein by reference in its entirety.

### TECHNICAL FIELD

The present disclosure generally relates to metal matrix composites, particularly to multilayer metal matrix composites, and a method for fabricating multilayer metal matrix composites.

### BACKGROUND

Metal matrix composites (MMCs) are composite materials with at least two constituent parts, one of which is a metal, while other part(s) may be a metal, ceramic, organic compound or any other material. MMCs are made by dispersing a reinforcing material into a metal matrix. The reinforcing material is usually added to help improve the properties of the metal matrix. Due to their superior strength to weight ratio, high temperature resistance, and corrosion resistance compared to conventional materials, MMCs have become applicable in different industries. For example, aluminum metal matrix composites (AMMCs) are a group of MMCs that have improved mechanical properties and amenability to conventional processing techniques.

Methods such as spray decomposition, liquid metal infiltration, powder metallurgy, squeeze casting, mechanical alloying, compocasting, and other techniques have been used in the fabrication of AMMCs. However, these methods have been associated with shortcomings, such as long process times, high production costs, or poor reinforcement of properties. Therefore, there is a need in the art for a simple method to fabricate MMCs with improved properties.

### SUMMARY

This summary is intended to provide an overview of the subject matter of the present disclosure, and is not intended to identify essential elements or key elements of the subject matter, nor is it intended to be used to determine the scope of the claimed implementations. The proper scope of the present disclosure may be ascertained from the claims set forth below in view of the detailed description below and the drawings.

In one general aspect, the present disclosure is directed to a multilayer metal matrix composite that includes at least two side sheets, including a first side sheet and a second side sheet as well as a metal core sheet. The metal core sheet is positioned between the first side sheet and the second side sheet. In addition, the metal core sheet is coated with an electroless coating selected from the group consisting of Nickel-Phosphorus electroless coating, Nickel-Boron electroless coating, and combinations thereof, and is reinforced with a reinforcement material selected from the group consisting of Tungsten carbide, Aluminum oxide, polymeric reinforcements, and combinations thereof.

The above general aspect may include one or more of the following features. The metal core sheet may be any metal sheet in different implementations. As one example, the metal core sheet may be independently selected from the group consisting of aluminum, iron, nickel, gold, copper, tin, titanium, cobalt, magnesium, platinum, palladium, zirconium, silver, beryllium, an aluminum alloy, an iron based alloy, magnesium alloy, platinum alloy, palladium alloy, zirconium alloy, steel, brass, a silver alloy, a beryllium alloy, a super alloy, or any combinations thereof.

In some implementations, the side sheets may be any metal or non-metal sheet which can be used in accumulative roll bonding process. For example, the material of at least the first side sheet may be independently selected from the group consisting of aluminum, iron, nickel, gold, copper, tin, titanium, cobalt, magnesium, platinum, palladium, zirconium, silver, beryllium, an aluminum alloy, an iron based alloy, magnesium alloy, platinum alloy, palladium alloy, zirconium alloy, steel, brass, a silver alloy, a beryllium alloy, a super alloy, or any combinations thereof. Furthermore, the reinforcements may be selected from a group consisting of ceramic reinforcements such as Tungsten carbide and Aluminum oxide, polymeric reinforcements such as PTFE, and combinations thereof. The coating coated on the reinforced metal core sheet may be any coating. In some implementations, the coating coated on the metal core sheet may be selected from the group consisting of Nickel-Phosphorus electroless coating, Nickel-Boron electroless coating and/or combinations thereof. In some cases, a material of the second side sheet is selected from the group consisting of aluminum, iron, nickel, gold, copper, tin, titanium, cobalt, magnesium, platinum, palladium, zirconium, silver, beryllium, aluminum alloy, iron based alloy, magnesium alloy, platinum alloy, palladium alloy, zirconium alloy, steel, brass, silver alloy, beryllium alloy, super alloy, and combinations thereof. In one implementation the second side sheet includes a material that differs from the material of the first side sheet, while in other implementations the second side sheet includes a material that is substantially similar to the material of the first side sheet. In addition, in some cases, a fracture toughness of the composite is greater than that of pure aluminum.

In another general aspect, the present disclosure is directed to a method of fabricating a multilayer metal matrix composite. The method can include a first step of adding reinforcement particles to a metal core sheet to obtain a reinforced metal core sheet, a second step of coating at least one side of the reinforced metal core sheet to obtain a coated metal core sheet, and a third step of heat-treating the coated metal core sheet. A fourth step may include placing the heat-treated coated metal core sheet between at least two side sheets, to obtain a metal sandwich sheet, and there may be a fifth step of subjecting the sandwich metal sheet to the accumulative roll bonding process to obtain a metal-matrix composite sheet.

The above general aspect may include one or more of the following features. The metal core sheet can be any metal sheet in different implementations. For example, the metal core sheet may be independently selected from the group consisting of aluminum, iron, nickel, gold, copper, tin, titanium, cobalt, magnesium, platinum, palladium, zirconium, silver, beryllium, an aluminum alloy, an iron based alloy, magnesium alloy, platinum alloy, palladium alloy, zirconium alloy, steel, brass, a silver alloy, a beryllium alloy, a super alloy, or any combinations thereof.

In some implementations, the reinforcement particles may be selected from a group consisting of ceramic reinforcements such as Tungsten carbide and Aluminum oxide, polymeric reinforcements such as PTFE, and combinations thereof. In some implementations, the metal core sheet may be coated using physical vapor deposition (PVD) method, chemical vapor deposition method (CVD), and/or high velocity oxygen fuel thermal spray (HVOF). In one example the metal core sheet may be coated using electroless method. In one example, the electroless coating process can include a first step of preparing a metal core sheet; a second step of preparing an electroless bath; and a third step of placing the metal core sheet in the bath for a predetermined amount of time to perform the electroless coating process.

In other implementations, the coating may be selected from the group consisting of, Nickel-Phosphorus electroless coating, Nickel-Boron electroless coating and combinations thereof. The side sheets may be any metal or non-metal sheet which can be used in accumulative roll bonding process. In some implementations, the side sheets may be independently selected from the group consisting of aluminum, iron, nickel, gold, copper, tin, titanium, cobalt, magnesium, platinum, palladium, zirconium, silver, beryllium, an aluminum alloy, an iron based alloy, magnesium alloy, platinum alloy, palladium alloy, zirconium alloy, steel, brass, a silver alloy, a beryllium alloy, a super alloy, or any combinations thereof.

Furthermore, in some cases, the coating method used may be electroless coating in which the electroless coating process may include: preparing a metal core sheet; preparing an electroless bath; and placing the metal core sheet in the electroless bath for a predetermined amount of time to perform the electroless coating process. In some implementations, preparing a metal core sheet may include the steps of: cleaning an annealed metal core sheet with chemicals to remove unwanted materials from the surface of the metal core sheet; and washing the cleaned annealed metal core sheet to remove chemicals that may adhere to the surface of the metal core sheet. In some implementations, preparing an electroless bath may include: preparing an electroless solution; adding reinforcing particles to the prepared electroless solution; and adjusting the temperature of the electroless bath.

In one example, preparing a Nickel-Phosphorus electroless bath may include: filling half of the Nickel-Phosphorus electroless bath with water; adding Slotonip 71-1 solution to the Nickel-Phosphorus electroless bath as a starter; adding Slotonip 72 solution to the Nickel-Phosphorus electroless bath as a nickel solution; adding Slotonip 76 solution to the Nickel-Phosphorus electroless bath as a stabilizer; adding water to the Nickel-Phosphorus electroless bath to reach a predetermined total volume; adding the reinforcement particles to the Nickel-Phosphorus bath; and heating the Nickel-Phosphorus electroless bath.

As another example, preparing a Nickel-Boron electroless bath may include: filling half of the Nickel-Boron electroless bath with water; adding Nickel-Chloride to the Nickel-Boron electroless bath; adding Ethylenediamine solution to the Nickel-Boron electroless bath; adding Sodium-Hydroxide to the Nickel-Boron electroless bath; adding water to the Nickel-Boron electroless bath to reach a predetermined total volume; adding the reinforcement particles to the Nickel-Boron bath; adding Lead nitrate solution to the Nickel-Boron electroless bath; and heating the Nickel-Boron electroless bath.

In addition, in some cases, the accumulative roll bonding process can include a first step of accumulative roll bonding a first metal sandwich sheet; a second step of dividing the accumulative roll bonded first metal sandwich sheet into pieces; a third step of piling the pieces of the accumulative roll bonded first metal sandwich sheets to obtain a second metal sandwich sheet; and repeating the three previous steps for a predetermined number of cycles to obtain a metal matrix composite. In some cases, the reinforcement particles include Tungsten carbide particles with a particle size of approximately 4 microns. In one implementation, after the heat-treatment step, the morphology of the coated metal core sheet changes from amorphous to crystalline and a Ni₃P hard phase is formed. In another example, the metal-matrix composite sheet obtains metal characteristics after three cycles. In addition, in some implementations, the method further includes recharging the electroless bath by adding approximately 0.2 grams of solid Sodium-Borohydride per liter to the Nickel-Boron electroless bath approximately every 30 minutes, adding approximately 30 milliliters of an aqueous solution of 5 grams of Nickel Chloride per liter to the Nickel-Boron electroless bath approximately every hour, or adding approximately a solution of 10 milliliters per liter of Ethylenediamine to the Nickel-Boron electroless bath approximately every hour.

Other systems, methods, features and advantages of the implementations will be, or will become, apparent to one of ordinary skill in the art upon examination of the following figures and detailed description. It is intended that all such additional systems, methods, features and advantages be included within this description and this summary, be within the scope of the implementations, and be protected by the following claims.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 is a flowchart of an implementation of a method for fabricating a multilayer metal matrix composite;

FIG. 2 is a schematic representation of an implementation of an accumulative roll bonding process;

FIG. 3A is a scanning electron microscope (SEM) image of a Nickel-Phosphorus electroless coated aluminum core sheet before a heat-treatment process, according to an implementation of the present disclosure;

FIG. 3B depicts X-ray diffraction (XRD) results of a Nickel-Phosphorus electroless coated aluminum core sheet before a heat-treatment process, according to an implementation of the present disclosure;

FIG. 3C depicts an SEM image of a Nickel-Phosphorus electroless coated aluminum core sheet after addition of Tungsten carbide particles, according to an implementation of the present disclosure;

FIG. 3D depicts XRD results of a Nickel-Phosphorus electroless coated aluminum core sheet after addition of Tungsten carbide particles, according to an implementation of the present disclosure;

FIG. 3E depicts a SEM image of the Nickel-Phosphorus-Tungsten Carbide electroless coated aluminum core sheet after the heat treatment process;

FIG. 3F depicts XRD results of the Nickel-Phosphorus-Tungsten Carbide electroless coated aluminum core sheet after the heat treatment process;

FIG. 3G depicts a SEM image of a cross-section of the Nickel-Phosphorus-Tungsten Carbide electroless coated aluminum core sheet;

FIG. 4A depicts an SEM image of a Nickel-Phosphorus-Tungsten Carbide electroless coated aluminum core sheet before a heat treatment process, according to an implementation of the present disclosure;

FIG. 4B depicts XRD results of the Nickel-Phosphorus-Tungsten Carbide electroless coated aluminum core sheet before a heat treatment process, according to an implementation of the present disclosure;

FIG. 4C depicts a SEM image of a Nickel-Phosphorus-Tungsten Carbide electroless coated aluminum core sheet after a heat treatment process, according to an implementation of the present disclosure;

FIG. 4D shows X-ray diffraction (XRD) results of a Nickel-Phosphorus electroless coated aluminum core sheet after addition of Tungsten carbide particles, according to an implementation of the present disclosure;

FIG. 4E shows a SEM image of the Nickel-Boron-Tungsten carbide electroless coated aluminum core sheet after a heat-treatment process, according to an implementation of the present disclosure;

FIG. 4F shows X-ray diffraction (XRD) results of the Nickel-Boron-Tungsten carbide electroless coated aluminum core sheet after a heat-treatment process, according to an implementation of the present disclosure;

FIG. 5A shows a SEM image of an accumulative roll bonded sheet with a Nickel-Phosphorus-Tungsten carbide electroless composite coating after a first cycle, according to an implementation of the present disclosure;

FIG. 5B shows a SEM image of an accumulative roll bonded sheet with a Nickel-Phosphorus-Tungsten carbide electroless composite coating after a second cycle, according to an implementation of the present disclosure;

FIG. 5C shows a SEM image of an accumulative roll bonded sheet with a Nickel-Phosphorus-Tungsten carbide electroless composite coating after a third cycle, according to an implementation of the present disclosure;

FIG. 5D shows a SEM image of an accumulative roll bonded sheet with a Nickel-Phosphorus-Tungsten carbide electroless composite coating after a fifth cycle, according to an implementation of the present disclosure;

FIG. 6A shows a SEM image of an accumulative roll bonded sheet with a Nickel-Boron-Tungsten carbide electroless composite coating after a first cycle, according to an implementation of the present disclosure;

FIG. 6B shows a SEM image of an accumulative roll bonded sheet with a Nickel-Boron-Tungsten carbide electroless composite coating after a second cycle, according to an implementation of the present disclosure;

FIG. 7A is a stress-strain curve of an aluminum sheet;

FIG. 7B is a stress-strain curve of a multilayer aluminum matrix composite sheet with a Nickel-Boron coating, according to an implementation of the present disclosure;

FIG. 8A is a bar chart showing fracture toughness of a multilayer aluminum matrix composite sheet with a Nickel-Boron coating after each accumulative roll bonding process cycle, according to an implementation of the present disclosure;

FIG. 8B is a bar chart showing ultimate strength of a multilayer aluminum matrix composite sheet with a Nickel-Boron coating after each accumulative roll bonding process cycle, according to an implementation of the present disclosure;

FIG. 8C is a bar chart showing elongation of a multilayer aluminum matrix composite sheet with a Nickel-Boron coating after each accumulative roll bonding process cycle, according to an implementation of the present disclosure; and

FIG. 9 shows a series of SEM images of a fracture region of the multilayer aluminum matrix composite sheet after each cycle, according to an implementation of the present disclosure.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings. The following detailed description is presented to enable a person skilled in the art to make and use the methods and devices disclosed in exemplary embodiments of the present disclosure. For purposes of explanation, specific nomenclature is set forth to provide a thorough understanding of the present disclosure. However, it will be apparent to one skilled in the art that these specific details are not required to practice the disclosed exemplary embodiments. Descriptions of specific exemplary embodiments are provided only as representative examples. Various modifications to the exemplary implementations will be readily apparent to one skilled in the art, and the general principles defined herein may be applied to other implementations and applications without departing from the scope of the present disclosure. The present disclosure is not intended to be limited to the implementations shown, but is to be accorded the widest possible scope consistent with the principles and features disclosed herein.

As noted above, multilayer metal matrix composites (MMC) are composite materials. Generally, MMCs can include a metal core sheet and a plurality of side sheets. The metal core sheet may be coated with various types of coating. Multilayer metal matrix composites (MMCs) are typically associated with improved properties including but not limited to high specific strength, high specific modulus, high damping capacity, and good wear resistance, particularly as compared to unreinforced alloys.

The present disclosure is directed to MMCs, and a simple method for fabricating MMCs with improved properties. For example, in this method, reinforcement particles with desired reinforcing properties may first be added to a metal core sheet to obtain a reinforced metal core sheet. The reinforced metal core sheet may then be coated with a coating which may be associated with the desired properties for specific uses. The coated metal core sheet may then be placed between at least two side sheets to obtain an initial composite, or a “metal sandwich” sheet. The metal sandwich sheet can be subjected to accumulative roll bonding for a number of cycles to obtain a multilayer metal matrix composite. The as-prepared multilayer metal matrix composite includes enhanced properties relative to multilayer metal composites prepared using conventional accumulative roll bonding process. Furthermore, such enhanced properties may be obtained in a fewer number of cycles as compared to the number of cycles required to obtain the same results using conventional accumulative roll bonding processes. Various implementations of this improved method will be discussed in greater detail below.

### Fabrication of a Multilayer Metal Matrix Composite

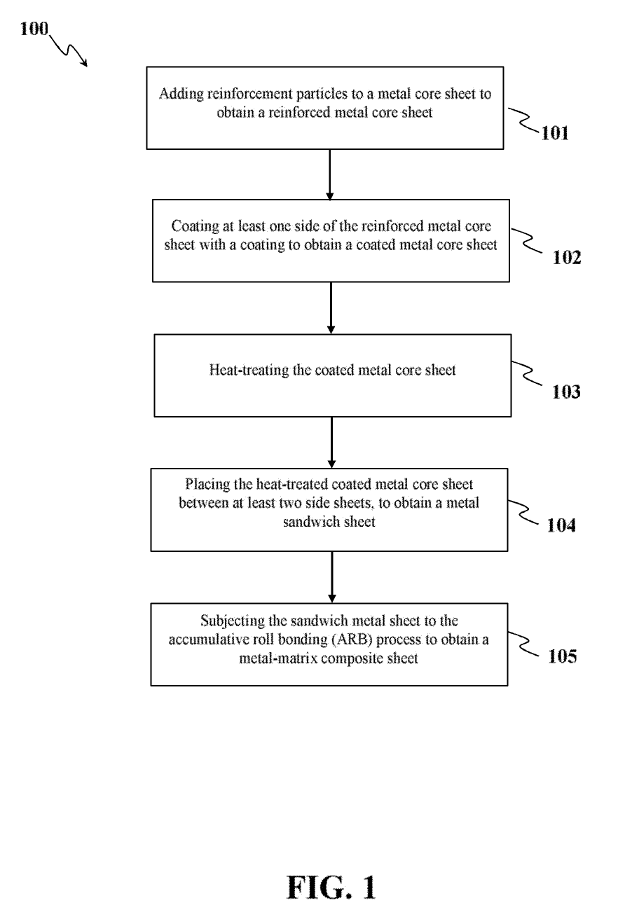

Referring to FIG. 1, a flowchart of a method 100 for fabricating a metal matrix composite, according to one or more implementations of the present disclosure, is presented. As shown in FIG. 1, in one implementation, the method 100 includes a first step 101 of adding reinforcement particles to a metal core sheet to obtain a reinforced metal core sheet, and a second step 102 of coating the reinforced metal core sheet to obtain a coated metal core sheet. In a third step 103, the coated metal core sheet is heat-treated, followed by a fourth step 104 of placing the heat-treated coated metal core sheet between at least two side sheets, to obtain an initial composite, or a metal sandwich sheet. Furthermore, a fifth step 105 involves subjecting the metal sandwich sheet to an accumulative roll bonding (ARB) process to obtain a multilayer metal-matrix composite sheet. Additional details regarding the method 100 are provided below.

With respect to first step 101, in some implementations, the metal core sheet may be independently selected from the group consisting of aluminum, iron, nickel, gold, copper, tin, titanium, cobalt, magnesium, platinum, palladium, zirconium, silver, beryllium, an aluminum alloy, an iron based alloy, magnesium alloy, platinum alloy, palladium alloy, zirconium alloy, steel, brass, a silver alloy, a beryllium alloy, a super alloy, or any combinations thereof. According to some implementations, reinforcement particles may be added to the metal core sheet to obtain a reinforced metal core sheet. The reinforcements may be selected from the group consisting of ceramic reinforcements such as Tungsten carbide and Aluminum oxide, polymeric reinforcements such as Polytetrafluoroethylene (PTFE), and combinations thereof.

In addition, with respect to second step 102, in some implementations, at least one side of the reinforced metal core sheet may be coated using a chemical vapor deposition method (CVD), a physical vapor deposition method (PVD), an electroless coating method, a high velocity oxygen fuel thermal spray (HVOF) method, or any other such coating methods. The coating may be selected from the group consisting of electroless coatings, such as Nickel-Phosphorus electroless coating, Nickel-Boron electroless coating, and combinations thereof. As an example, one electroless coating method may include steps of: (1) preparing the metal core sheet; (2) preparing an electroless bath; and (3) placing the prepared metal core sheet in the electroless bath to perform the electroless coating process.

Furthermore, in some implementations, preparing the metal core sheet may include steps of: (1) annealing a metal core sheet; (2) cleaning the annealed metal core sheet with a series of chemicals to remove unwanted materials from the surface of the metal core sheet; and (3) rinsing the cleaned metal core sheet with for example water to remove chemicals that may have adhered to the surface of the metal core sheet.

In one implementation, preparing the electroless bath may include steps of: (1) preparing an electroless solution; (2) adding reinforcing particles to the prepared electroless solution; and (3) adjusting the temperature of the electroless bath. The prepared metal core sheet may be placed in the prepared electroless bath for a predetermined amount of time to obtain an electroless coated metal core sheet.

Referring next to third step 103, in some implementations, the electroless coated metal core sheet may be further heat-treated. This can help increase the hardness of the provided electroless coating. To this end, the electroless coated metal core sheet is heated for a predetermined amount of time and in a predetermined temperature, to obtain a metal matrix composite core sheet.

With reference to fourth step 104, in some implementations, the metal matrix composite core sheet may be placed in between at least two side sheets to obtain a first initial composite, or a first metal sandwich sheet. In different implementations, the side sheets may be independently selected from the group consisting of aluminum, iron, nickel, gold, copper, tin, titanium, cobalt, magnesium, platinum, palladium, zirconium, silver, beryllium, an aluminum alloy, an iron based alloy, magnesium alloy, platinum alloy, palladium alloy, zirconium alloy, steel, brass, a silver alloy, a beryllium alloy, a super alloy, or any combinations thereof, or any other metal or non-metal sheets.

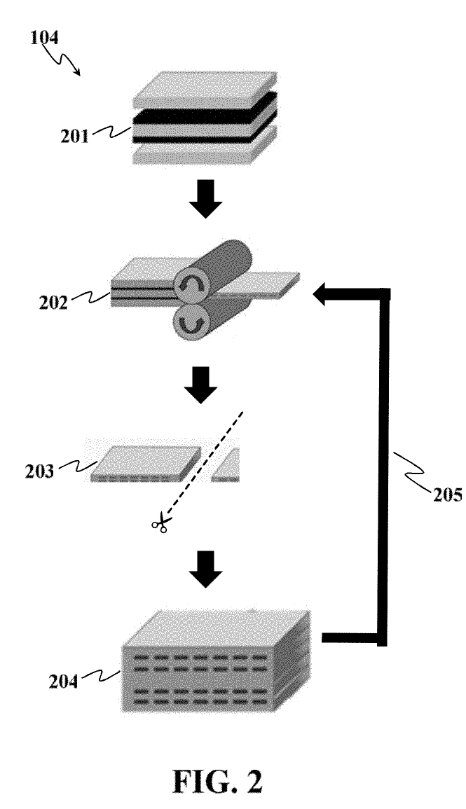

Referring now to FIG. 2, some details are provided with respect to fifth step 105. In some implementations, the accumulative roll bonding (ARB) process may be understood to follow a preliminary step 201 of placing a metal matrix core sheet between at least two side sheets to obtain the first initial composite, or the first metal sandwich sheet (as described in fourth step 104 of FIG. 1). This is followed by a first step 202 of performing a first cycle of the ARB process on the first metal sandwich sheet; a second step 203 of dividing the accumulative roll bonded first metal sandwich sheet into pieces; a third step 204 of piling or combining the pieces of the accumulative roll bonded first metal sandwich sheets to obtain a second initial composite, or a second metal sandwich sheet; and then repeating the steps 202, 203, and 204 for a predetermined number of cycles as shown by an arrow 205 to obtain a multilayer metal matrix composite sheet.

### EXAMPLE 1

### Fabrication of an Aluminum Metal Matrix Composite

For purposes of clarity, one example is provided in which a multilayer aluminum matrix composite is fabricated according to an implementation of the present disclosure. However, it should be understood that in other implementations, one or more of the steps disclosed herein can be omitted as desired, or additional steps may be included. As described above, in one implementation, the method for fabrication of a multilayer aluminum matrix composite may include the steps of: (1) coating an aluminum core sheet to obtain a coated aluminum core sheet; (2) heat-treating the coated aluminum core sheet; (3) placing the heat-treated coated aluminum core sheet between at least two side sheets, to obtain an initial composite, or a metal sandwich sheet; and (4) performing the accumulative roll bonding (ARB) process on the sandwich metal sheet to obtain a metal-matrix composite sheet. In this example, the aluminum core sheet was coated using an electroless method. To this end, AA1100 sheets of 20×6×0.5 mm (length×width×thickness) were used. Initially, all sheets were annealed at a temperature of approximately 350° C. for approximately 2 hours. At least one of the annealed sheets could be used as the core sheet. As an example, Tungsten carbide particles with a particle size of approximately 4 microns were added as reinforcement particles to the core sheet. Before performing the electroless process on the core sheet, the annealed core sheet was prepared. The preparation process in this example included (1) a first step of mechanically polishing the annealed core sheet using about a 2000 grit sandpaper; (2) a second step of degreasing the polished core sheet by immersing in an acetone solution in an ultrasonic device for approximately 20 minutes; (3) a third step of washing the core sheet of step (2) with water; (4) a fourth step of pickling the core sheet of step (3); (5) a fifth step of activating the surface of the core sheet of step (4) using a 1:1 nitric acid solution for approximately 30 seconds; (6) a sixth step of washing the core sheet of step 5 with water; (7) a seventh step of placing the core sheet of step (6) in a zinc solution for approximately 30 seconds; (8) an eighth step of placing the core sheet of step (7) in a 1:1 nitric acid solution for approximately 30 seconds to remove the aluminum oxide layer while leaving the zinc particles on the sheet; (9) a ninth step of washing the core sheet of step (8) with water; (10) a tenth step of placing the core sheet of step (9) in a zinc solution for approximately 1 minute to replace the removed aluminum oxide layer with a zinc layer; and (11) an eleventh step of washing the core sheet of step (10) with water and thereby obtaining a prepared aluminum core sheet for the electroless coating process.

In order to remove the zinc layer from the prepared aluminum core sheet and apply the electroless coating on the sample, an acidic Nickel electroless bath was used. Due to the weak properties of Nickel-Boron acidic electroless coating, the prepared aluminum core sheet was first placed in a Nickel-Phosphorus electroless bath for approximately 10 minutes to facilitate the application of a Nickel-Phosphorus electroless coating on the prepared aluminum core sheet as an undercoat. According to one implementation of the present disclosure, the fabrication process of 1 liter of Nickel-Phosphorus electroless solution for a Nickel-Phosphorus electroless bath may include: (1) a first step of filling half of the electroless bath with water; (2) a second step of adding approximately 166 milliliters of Slotonip 71-1 solution to the bath as a starter; (3) a third step of adding approximately 70 milliliters of Slotonip 72 solution to the bath as a nickel solution; (4) a fourth step of adding approximately 7 milliliters of Slotonip 76 solution to the bath as a stabilizer; (5) a fifth step of adding water to the bath to reach a total volume of approximately 1 liter; (6) a sixth step of adding approximately 40 milliliters of an aqueous solution of tungsten carbide with a concentration of approximately 1 gram of Tungsten carbide in 1 liter of distilled water as the reinforcement particles; and (7) a seventh step of heating the Nickel-Phosphorus electroless bath to reach a temperature of approximately 85° C.

The prepared aluminum core sheet was then placed in the prepared Nickel-Phosphorus electroless bath for approximately 60 minutes to apply a Nickel-Phosphorus coating on the prepared aluminum core sheet as an undercoat.

Furthermore, in one implementation of the present disclosure, the fabrication process of approximately 1 liter of Nickel-Boron electroless solution for the Nickel-Boron electroless bath may include (1) a first step of filling approximately half of the Nickel-Boron electroless bath with water; (2) a second step of adding approximately 24 grams of Nickel-Chloride to the Nickel-Boron electroless bath; (3) a third step of adding approximately 59 milliliters of Ethylenediamine solution to the Nickel-Boron electroless bath; (4) a fourth step of adding approximately 39 grams of Sodium-Hydroxide to the Nickel-Boron electroless bath; (5) a fifth step of adding water to the Nickel-Boron electroless bath to reach a total volume of approximately 1 liter; (6) a sixth step of adding approximately 40 milliliters of an aqueous solution of Tungsten carbide with a concentration of approximately 1 gram of Tungsten carbide in 1 liter of distilled water as the reinforcements particles to the Nickel-Boron electroless bath; (7) a seventh step of adding approximately 10 milliliters of Lead nitrate solution with a concentration of approximately 0.01 gram per liter to the Nickel-Boron electroless bath; and (8) an eighth step of heating the Nickel-Boron electroless bath to reach a temperature of approximately 95° C.

In some cases, due to the high activity of the reducing agent in the Nickel-Boron electroless bath, the Nickel-Boron electroless bath may decrease in effectiveness after approximately one hour. Therefore, the Nickel-Boron electroless bath may be recharged by adding approximately 0.2 grams of solid Sodium-Borohydride per liter to the Nickel-Boron electroless bath approximately every 30 minutes, adding approximately 30 milliliters of an aqueous solution of 5 grams of Nickel Chloride per liter to the Nickel-Boron electroless bath approximately every hour, and/or adding approximately a solution of 10 milliliters per liter of Ethylenediamine to the Nickel-Boron electroless bath approximately every hour.

The prepared aluminum core sheet with the Nickel-Phosphorus undercoating is then placed in the prepared Nickel-Boron electroless bath to facilitate the application a Nickel-Boron coating on the prepared aluminum core sheet with the Nickel-Phosphorus undercoating, thereby obtaining a Nickel-Boron and Nickel-Phosphorus coated aluminum core sheet which hereinafter is referred to as the electroless coated aluminum core sheet.

As noted earlier, in one implementation of the present disclosure, heat-treatment can be used to increase the hardness of the provided electroless coating. For the samples including Nickel-Boron electroless coating, the heat-treatment process was performed by heating the samples for approximately 1 hour at a temperature of about 450° C. and in an argon atmosphere. For the samples including the Nickel-Phosphorus electroless coating, there was no need for an argon atmosphere and the samples are heated to a temperature of 450° C. in an air atmosphere and then cooled in the environment, to obtain a heat-treated, electroless aluminum core sheet, which is hereinafter referred to as the aluminum matrix composite core sheet. Finally, the aluminum matrix composite core sheet was ready for the ARB process.

In this Example, to perform the ARB process, (1) first, the annealed aluminum side sheets were wire-brushed; then (2) the aluminum matrix composite core sheet was placed between at least two annealed and wire-brushed aluminum side sheets, such that the coated side of the aluminum matrix composite core sheet faced the wire-brushed side of the aluminum side sheets, thereby obtaining a first initial aluminum composite, or a first aluminum sandwich sheet. The first cycle of the accumulative roll bonding process was performed on the first aluminum sandwich sheet to obtain an accumulative roll bonded first aluminum sandwich sheet. The accumulative roll bonded first aluminum sandwich sheet obtained a thickness of the primary sheet after the first cycle. The accumulative roll bonded first aluminum sandwich sheet was cut into two halves and the two halves were piled to obtain a second initial aluminum composite, or a second aluminum sandwich sheet. The accumulative roll bonding process was repeated on the second aluminum sandwich sheet and the accumulative roll bonding process was continued for 4 cycles, to obtain a multilayer aluminum matrix composite sheet.

### EXAMPLE 2

### Characterization Tests

In Example 2, the results of some characterization tests performed on the multilayer aluminum matrix composite sheet, prepared as described in detail in connection with Example 1, are presented.

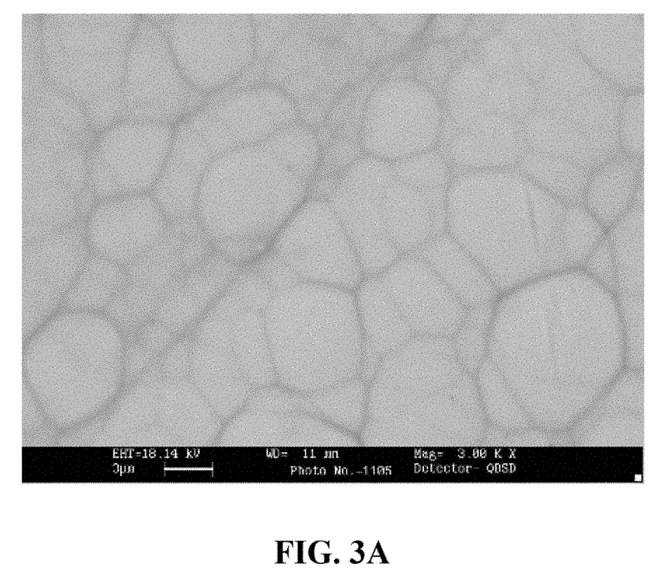

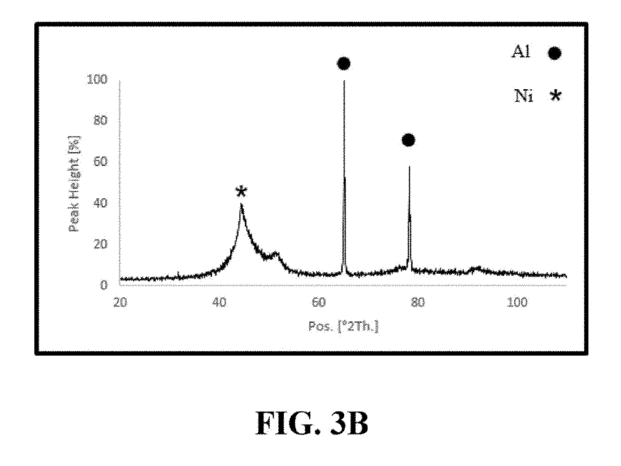

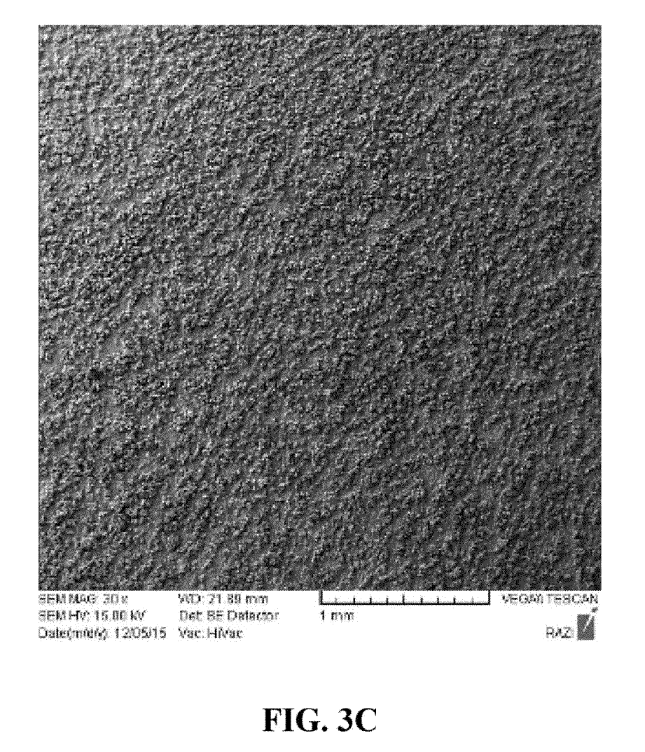

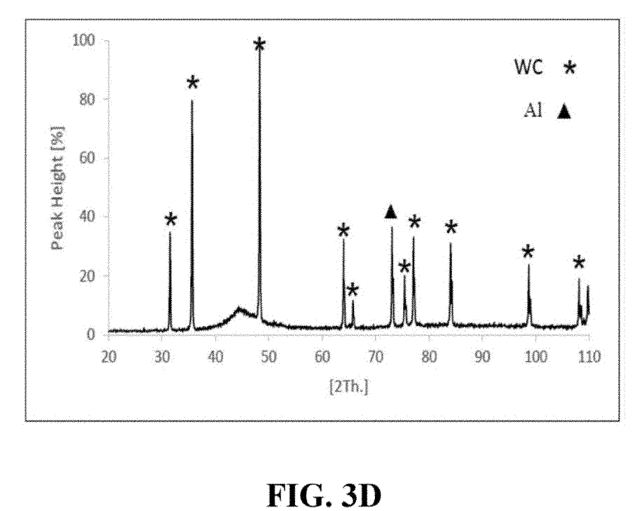

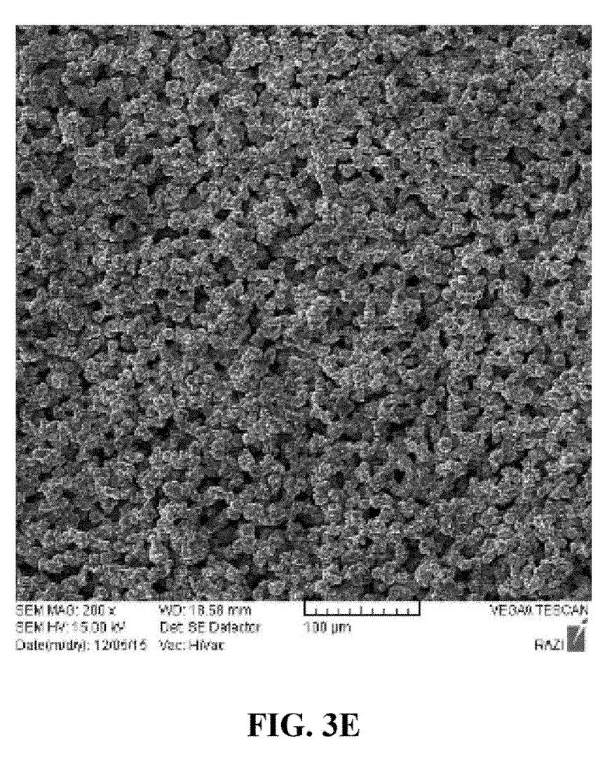

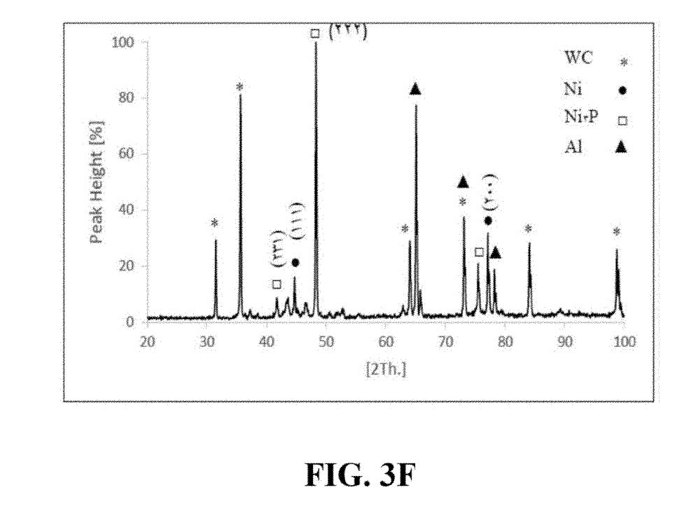

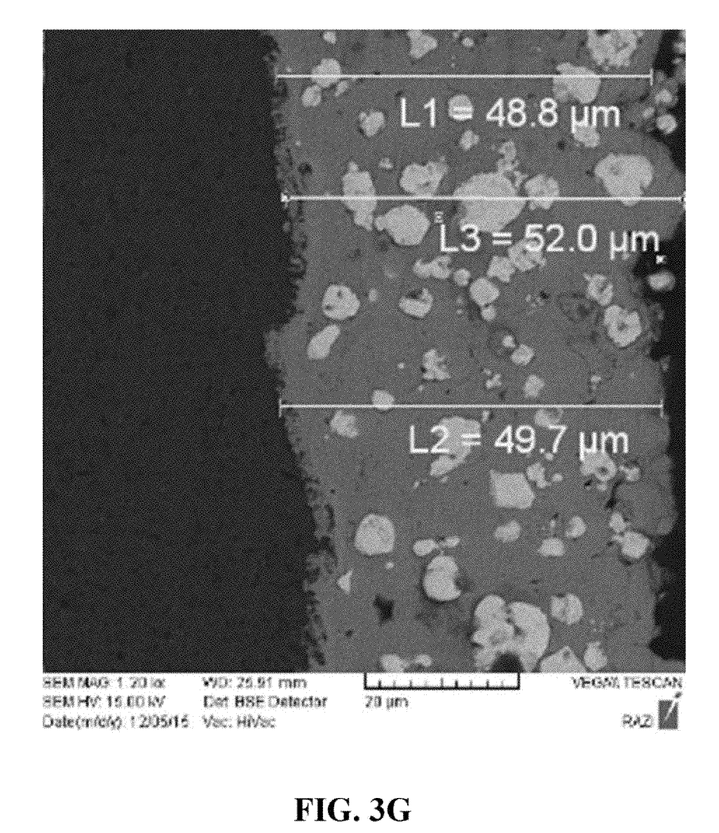

Referring first to FIGS. 3A-3F, a series of images and results are provided. In FIG. 3A, a SEM image of the Nickel-Phosphorus electroless coated aluminum core sheet before the heat-treatment process is shown. In FIG. 3A it can be seen that the Nickel-Phosphorus electroless coating has a cauliflower-like shape. FIG. 3B shows the X-ray diffraction (XRD) results of the Nickel-Phosphorus electroless coated aluminum core sheet before the heat-treatment process. As shown in FIG. 3B the Nickel-Phosphorus electroless coated aluminum core sheet can be seen to have an amorphous structure. FIG. 3C is a SEM image of the Nickel-Phosphorus electroless coated aluminum core sheet after adding Tungsten carbide particles. As seen in FIG. 3C, by adding the Tungsten carbide particles, the morphology becomes porous.

Furthermore, FIG. 3D presents the X-ray diffraction (XRD) results of the Nickel-Phosphorus electroless coated aluminum core sheet after the addition of Tungsten carbide particles. In FIG. 3D, it can be seen that the XRD results confirm the existence of Tungsten carbide particles in the structure. In FIG. 3E a SEM image of the Nickel-Phosphorus-Tungsten Carbide electroless coated aluminum core sheet after the heat treatment process is shown. As seen in FIG. 3E, after the heat-treatment process, the morphology changes from amorphous to crystalline. In addition, the XRD results of the Nickel-Phosphorus-Tungsten Carbide electroless coated aluminum core sheet after the heat treatment process are presented in FIG. 3F. As shown in FIG. 3F, Ni₃P hard phase is formed after the heat-treatment process. FIG. 3G depicts a SEM image of a cross-section of the Nickel-Phosphorus-Tungsten Carbide electroless coated aluminum core sheet. Referring to FIG. 3G, it can be seen that the particles have not been agglomerated.

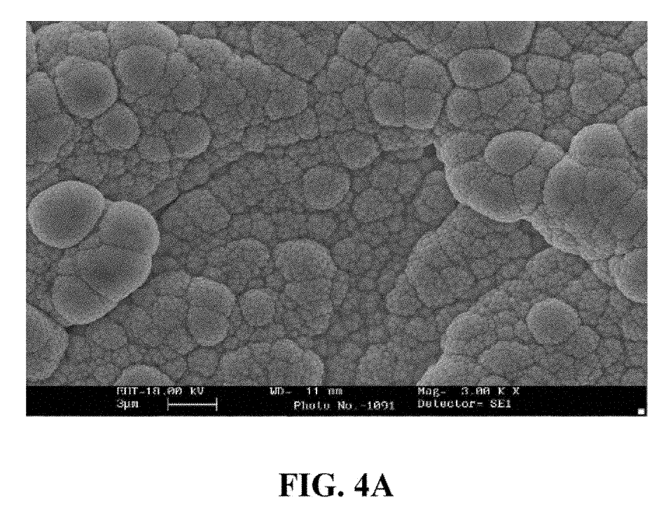

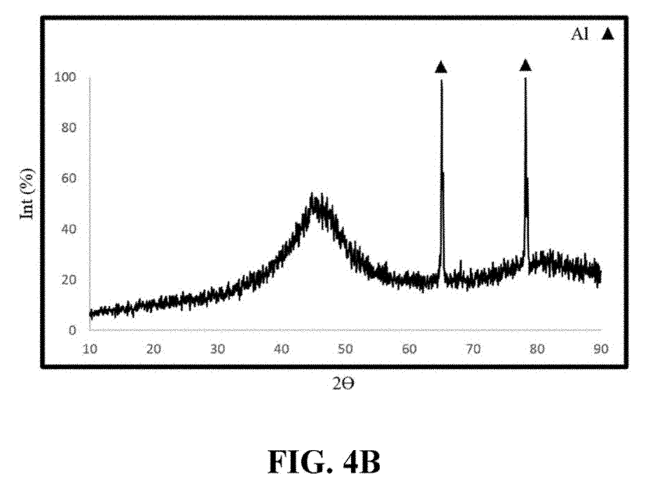

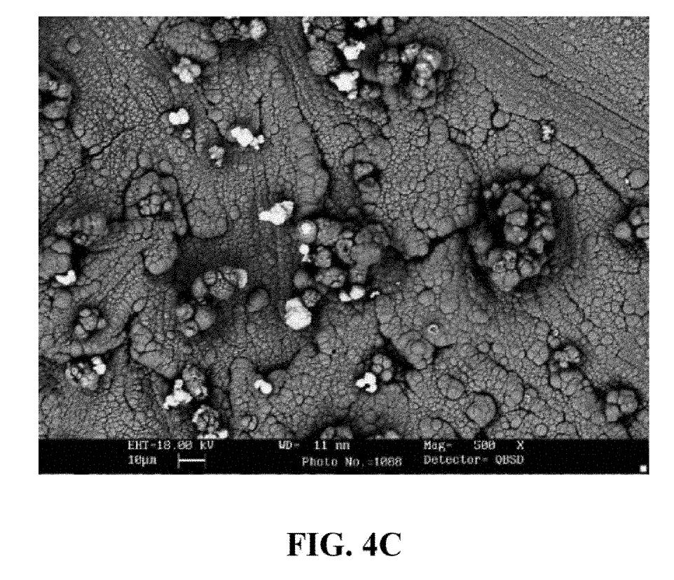

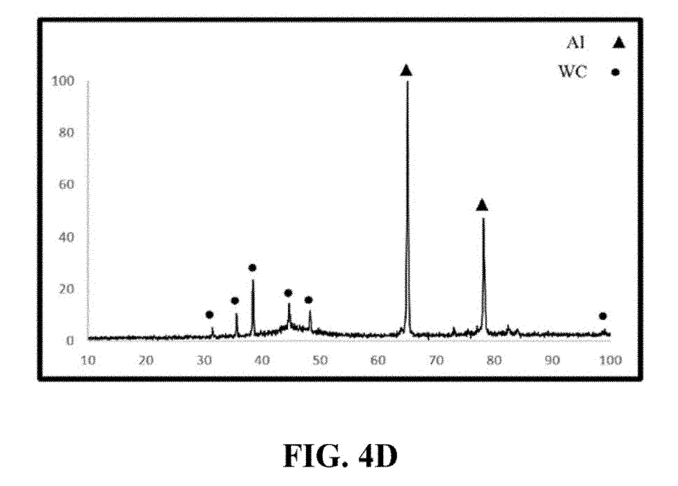

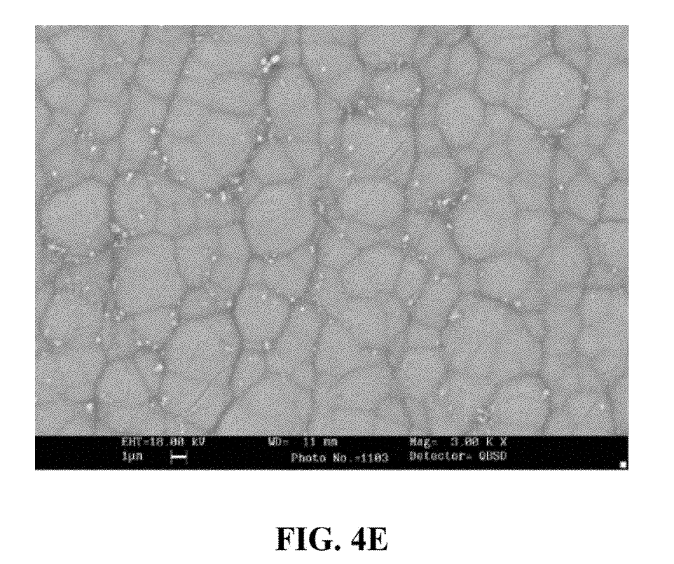

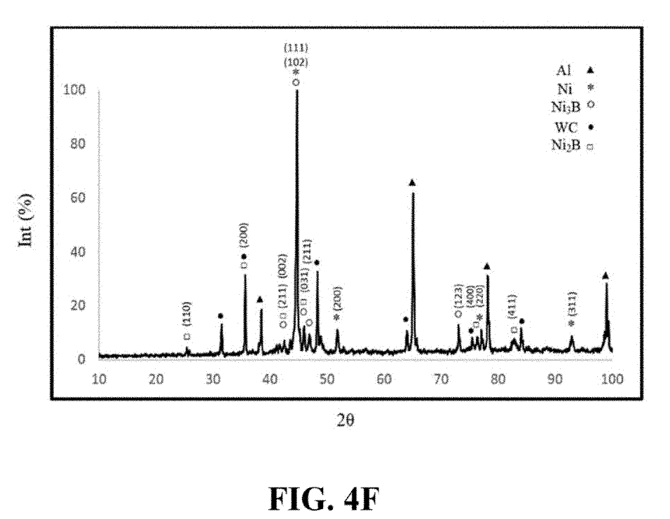

Referring next to FIGS. 4A-4F, a series of images and results are provided. In FIG. 4A a SEM image of the Nickel-Boron electroless coated aluminum core sheet before the heat-treatment process is presented. In FIG. 4A the Nickel-Boron electroless coated aluminum core sheet can be seen to include a cauliflower-like shape. FIG. 4B provides the X-ray diffraction (XRD) results of the Nickel-Boron electroless coating before the heat-treatment process. Referring to FIG. 4B the Nickel-Boron electroless coating can be seen to have an amorphous structure. Next, in FIG. 4C, a SEM image of the Nickel-Boron electroless coated aluminum core sheet after adding Tungsten carbide particles is illustrated. It can be seen in FIG. 3C that by adding the Tungsten carbide particles, the morphology becomes porous.

FIG. 4D presents the X-ray diffraction (XRD) results of the Nickel-Phosphorus electroless coated aluminum core sheet after the addition of Tungsten carbide particles. According to FIG. 4D, the XRD results confirm the existence of Tungsten carbide particles in the structure. FIG. 4E is a SEM image of the Nickel-Boron-Tungsten carbide electroless coated aluminum core sheet after the heat-treatment process. As shown in FIG. 4E, after the heat-treatment process, the morphology changes from amorphous to crystalline, and the particles on the surface penetrate into the matrix. In FIG. 4F the X-ray diffraction (XRD) results of the Nickel-Boron-Tungsten carbide electroless coated aluminum core sheet after the heat-treatment process are presented. As shown in FIG. 4F, Ni₂B and Ni₃B hard phases and Ni fine phase are formed after the heat-treatment process.

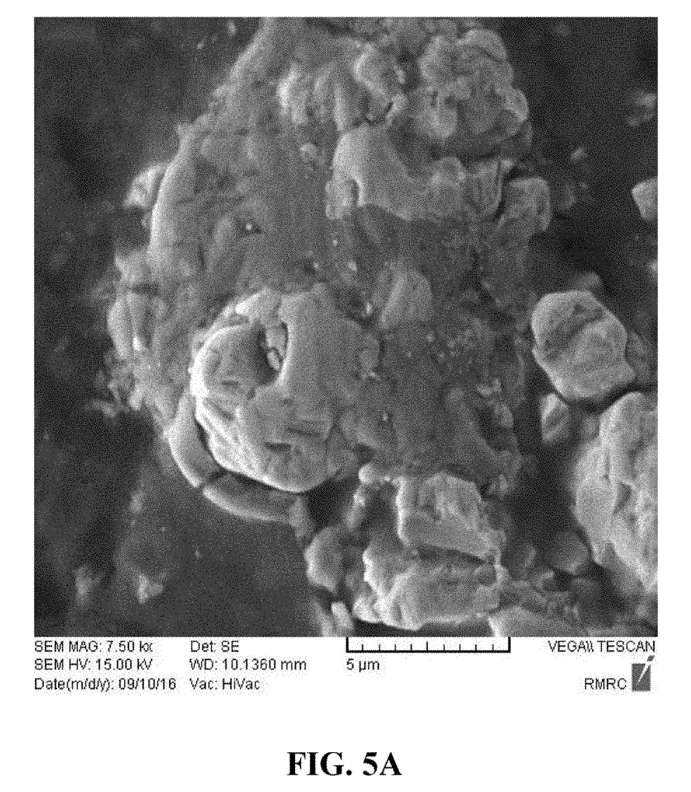

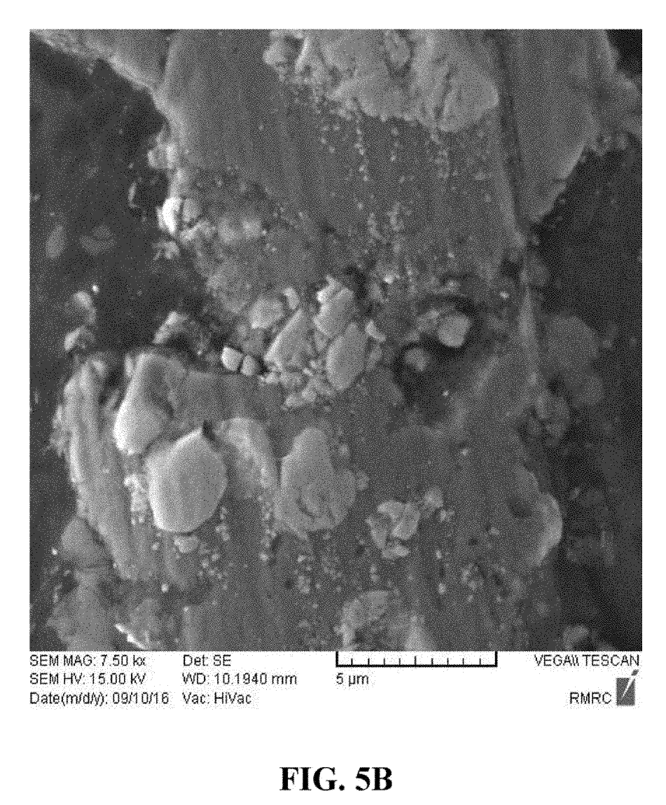

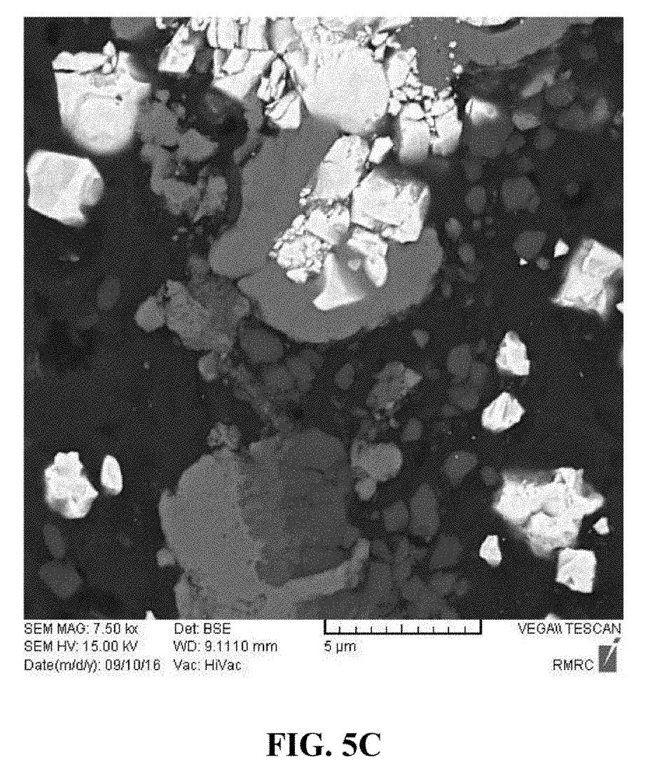

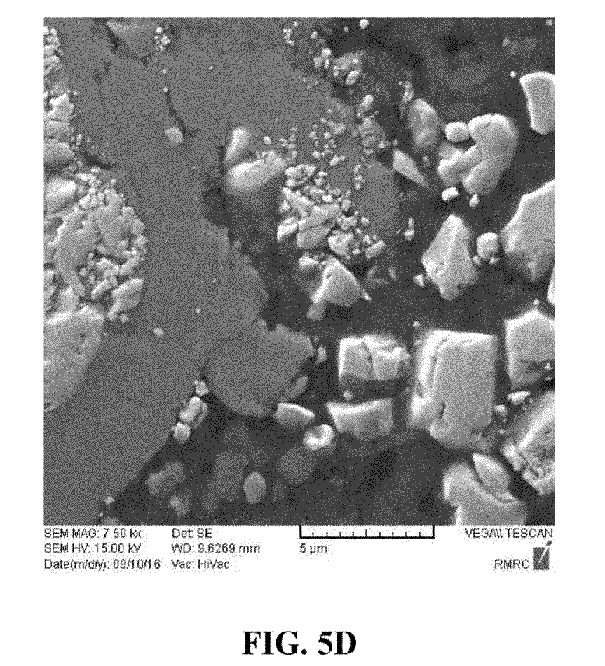

In order to evaluate the accumulative roll bonding process and characteristics of the obtained composite, the distribution of reinforcement phases was considered. FIG. 5A is a SEM image of the accumulative roll bonded sheet with the Nickel-Phosphorus-Tungsten carbide electroless composite coating after the first cycle. As shown in FIG. 5A, the composite coating is broken in the first phase which causes the adhesion of the three aluminum layers, FIG. 5B is a SEM image of the accumulative roll bonded sheet with the Nickel-Phosphorus-Tungsten carbide electroless composite coating after the second cycle. Referring to FIG. 5B, the composite after the second cycle, the tungsten carbide particles, and the coating are broken and distributed in the matrix.

In addition, FIG. 5C illustrates a SEM image of the accumulative roll bonded sheet with the Nickel-Phosphorus-Tungsten carbide electroless composite coating after the third cycle. Referring to FIG. 5C, it can be seen that the particles which are broken and distributed in the matrix do not undergo further braking because of the softness of the matrix. FIG. 5D is a SEM image of the accumulative roll bonded sheet with the Nickel-Phosphorus-Tungsten carbide electroless composite coating after the fifth cycle. In FIG. 5D, it can be seen that the Tungsten carbide and coating particles are broken into micrometric particles and distributed finely in the matrix.

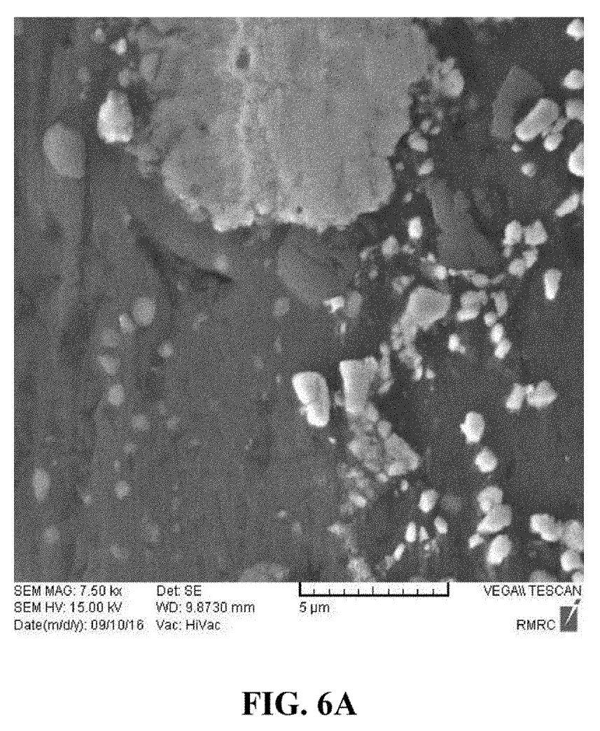

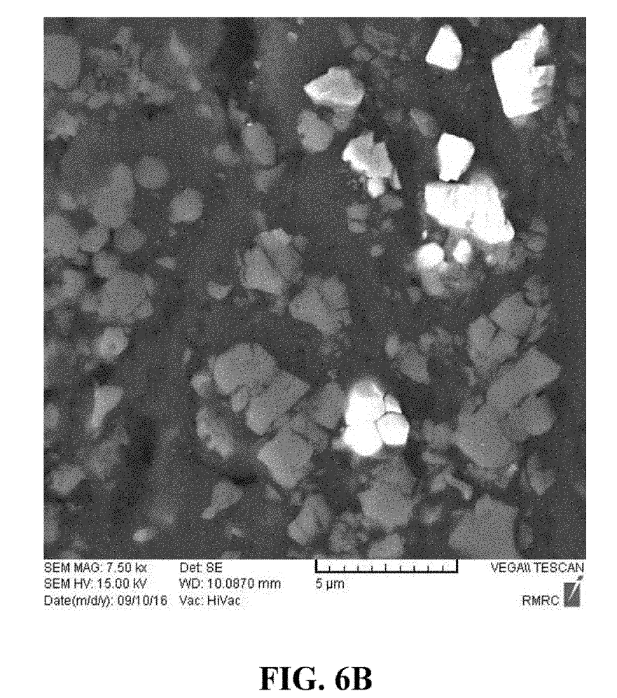

FIG. 6A shows a SEM image of the accumulative roll bonded sheet with the Nickel-Boron-Tungsten carbide electroless composite coating after the first cycle. As shown in FIG. 6A, the composite coating is broken in the first phase which causes the adhesion of the 3 aluminum layers, and the smaller particles show the Nickel-Phosphorus undercoating. FIG. 6B is a SEM image of the accumulative roll bonded sheet with the Nickel-Boron-Tungsten carbide electroless composite coating after the second cycle. As shown in FIG. 6B, in the second cycle, the remaining parts of the coating are broken and penetrate into the matrix. The breaking of the Nickel-Boron electroless coating hard phases (lighter phases) can be seen in frangible form, and some parts of the Nickel-Phosphorus undercoating and the Nickel-Boron electroless coating in fine phases (darker phases) can also be seen.

Next, FIG. 6C illustrates a SEM image of the accumulative roll bonded sheet with the Nickel-Boron-Tungsten carbide electroless composite coating after the third cycle. As shown in FIG. 6C, the particles which are broken and distributed in the matrix do not undergo further breaking due to the softness of the matrix. FIG. 6D is a SEM image of the accumulative roll bonded sheet with the Nickel-Boron-Tungsten carbide electroless composite coating after the fifth cycle. Referring to FIG. 6D, it can be seen that there are only some parts of the Nickel-Boron electroless coating and fine particles of Tungsten Carbide that are covered by the finer Nickel-Phosphorus electroless phase. The remaining particles and phases do not change after the fourth phase and the reinforcement particles on the sheet obtain their final distribution.

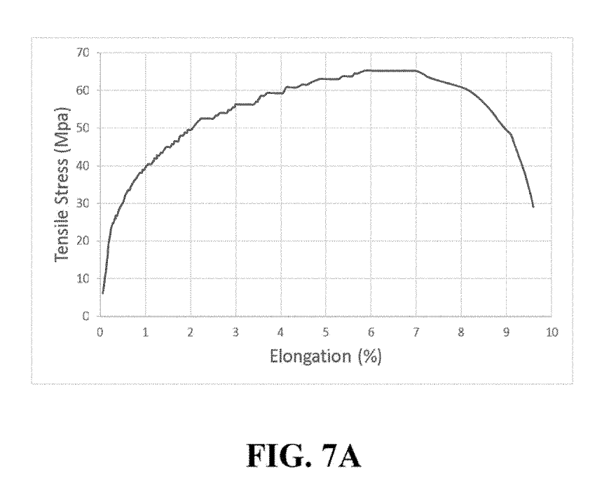

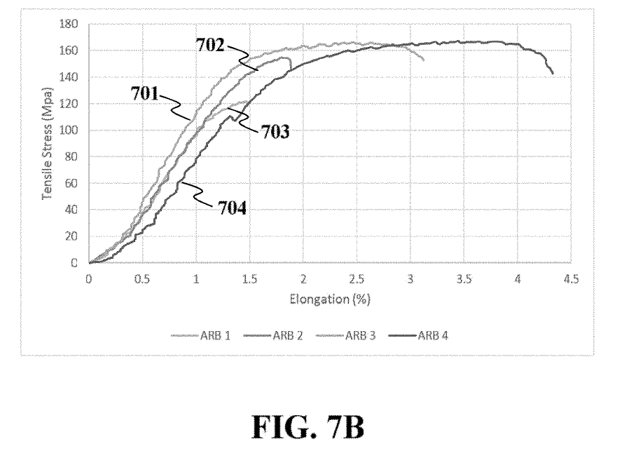

In order to evaluate the mechanical properties of the obtained multilayer aluminum matrix composite sheet, a uniaxial tensile test was used. FIG. 7A presents the stress-strain curve of an exemplar aluminum sheet which has been used as a reference for comparison. In FIG. 7B the stress-strain curves of the multilayer aluminum matrix composite sheet after the first cycle 701, second cycle 702, third cycle 703 and fourth cycle 704 of the accumulative roll bonding process are shown. During the first cycle 701, as there are hard layers in the coating, the sheet is highly frangible and the yield stress and failure points are congruous. In the second cycle 702, as the Nickel-Boron-Tungsten carbide electroless composite coating breaks, the fracture force, the yield stress and the elongation percentage improve slightly. In the third cycle 703, the multilayer aluminum matrix composite sheet obtains its metal characteristics. In the fourth cycle 704, the sheet has obtained its highest elongation and toughness, as the sheet reaches its final structure. The elasticity modulus has changed in the second, third and fourth cycles due to the transmutation of the sheet in these cycles. For a closer evaluation of the characteristics of the composite sheets, the information of the stress-strain curves was extracted.

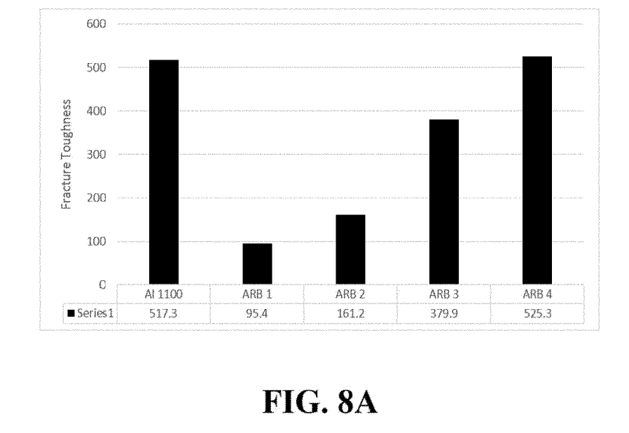

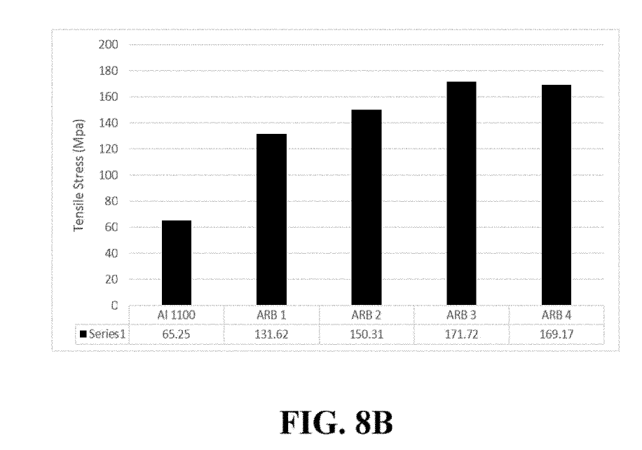

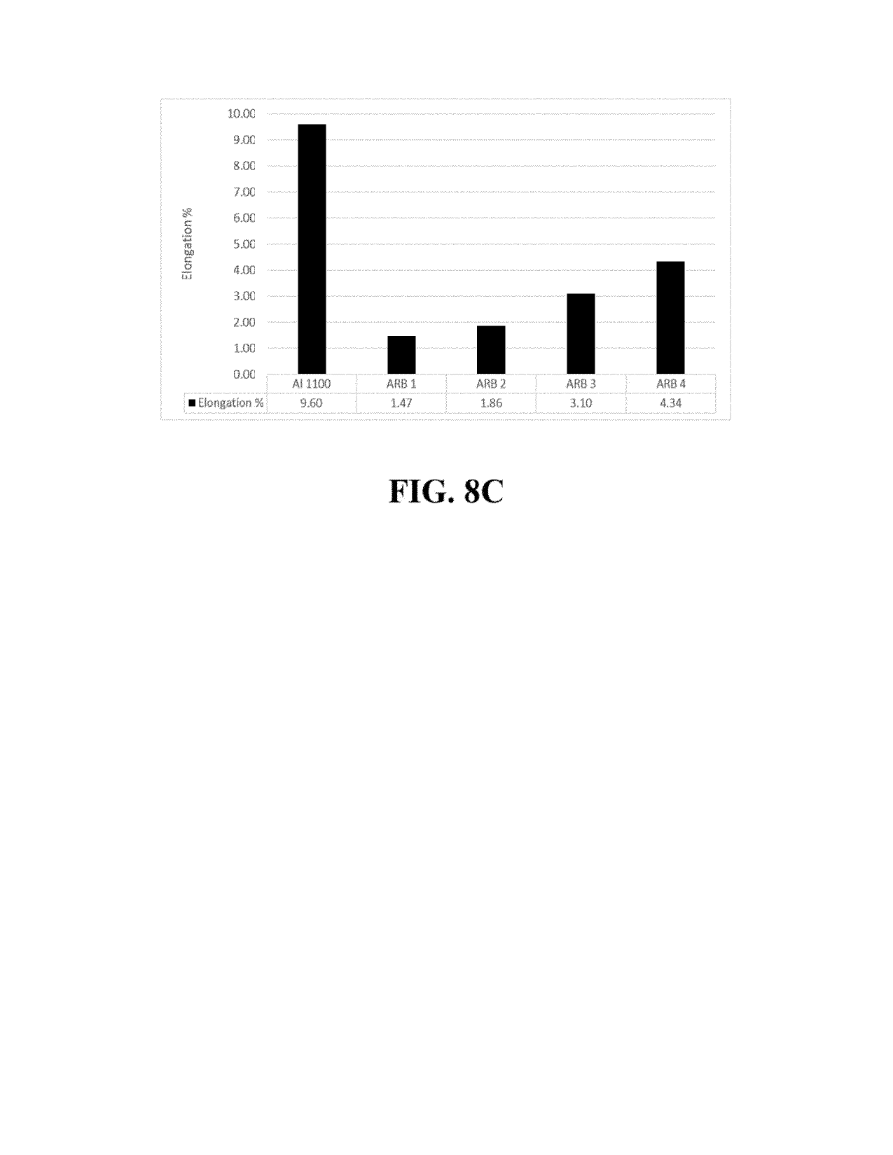

FIG. 8A presents the changes in fracture toughness due to increasing the number of cycles. In the fourth cycle, the fracture toughness of the composite sheet is greater than that of pure aluminum, which is one of the important characteristics of the method. In FIG. 8B, ultimate strength changes are evaluated, reflecting a three times growth compared to the primary sheet. Referring to FIG. 8C, a 50% decrease in the elongation rate in the last cycle for the primary aluminum sheet can be seen.

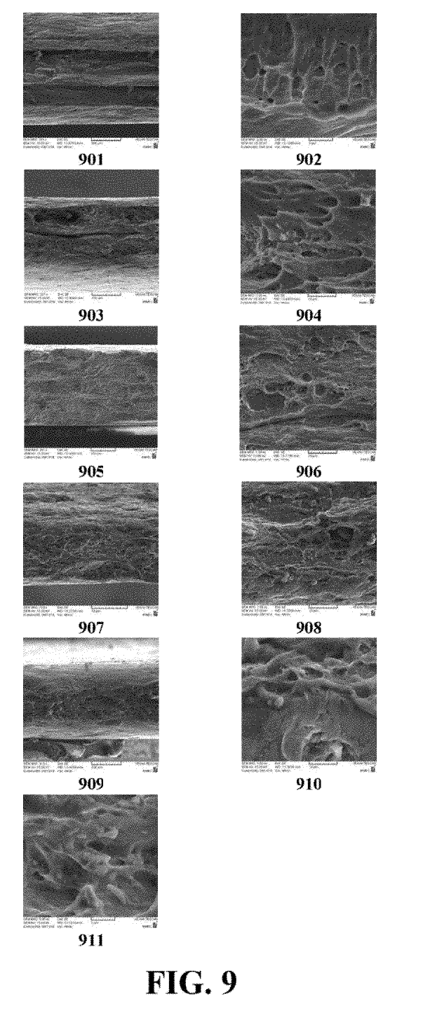

To investigate the type of sheet deflection during the uniaxial tensile test, the fracture region was also investigated. FIG. 9 presents a series of SEM images of the fracture region of the multilayer aluminum matrix composite sheet, after each cycle. Referring to FIG. 9, the fracture region of the multilayer aluminum matrix composite after the first cycle in lower magnification is shown in a first image 901. It can be seen that—in the upper portion of the image 901—some parts of the side sheets are visible, which are the reason for the brittle fracture in this cycle. In a second image 902 a SEM image of the multilayer aluminum matrix composite after the first cycle with higher magnification is shown. In the lateral areas of second image 902 soft fractures can be seen which can be related to aluminum regions.

A third image 903 depicts a SEM image of the multilayer aluminum matrix composite after the second cycle with a lower magnification. In third image 903 better distribution has been obtained in some regions of the sheet compared to other parts, which has led to a difference in the mechanical properties of the various areas of the sheet. In the center of the fracture area, a line of dissociation is observed which is related to pure aluminum, in the center of the sheet. This area has weaker mechanical properties relative to the upper and lower parts. This difference in properties results in brittle fracture of the sheet.

A fourth image 904 shows a SEM image of the multilayer aluminum matrix composite after the second cycle with a higher magnification. In fourth image 904, it can be understood that the cavities refer to the areas with better distribution, which have gone through a soft fracture.

Next, a fifth image 905 is a SEM image of the multilayer aluminum matrix composite after the third cycle with a lower magnification. Referring to fifth image 905, it can be seen that a uniform fracture has occurred after the third cycle. In this cycle, the phases and the reinforcing particles have an appropriate distribution throughout the sheet. In a sixth image 906, a SEM image of the multilayer aluminum matrix composite after the third cycle with a higher magnification is presented. As shown in sixth image 906, in higher magnifications, the soft sheet defects are visible.

Next a seventh image 907 illustrates a SEM image of the multilayer aluminum matrix composite after the fourth cycle with a lower magnification. In seventh image 907, in the fourth cycle, soft and hard fracture occur simultaneously which is related to the characteristic of UFG materials. With respect to an eighth image 908, a SEM image of the multilayer aluminum matrix composite after the fourth cycle with a higher magnification is presented. As shown in eighth image 908, at higher magnifications, soft fracture along with brittle fracture can be seen in same areas.

In a ninth image 909, a SEM image of the multilayer aluminum matrix composite after the fifth cycle with a lower magnification is provided. Referring to ninth image 909, in the fifth cycle, soft and hard fracture occur simultaneously which is related to the characteristic of UFG materials. Due to the nanodimensional size of the particles, and well distribution of the reinforcing particles in the matrix, the type of fracture has not changed in the fifth cycle.

Furthermore, a tenth image 910 shows a SEM image of the multilayer aluminum matrix composite after the fifth cycle with a higher magnification. Referring to tenth image 910, at higher magnifications, soft fracture along with brittle fracture can be seen in same areas. Finally, with respect to an eleventh image 911, a SEM image of the multilayer aluminum matrix composite after the fifth cycle with even higher magnification compared to image 910 is provided. It can be seen that the well distribution of the reinforcement and coating particles all over the matrix and their adhesion in the fracture region are visible in eleventh image 911.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure, and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

While various implementations have been described, the description is intended to be exemplary, rather than limiting and it will be apparent to those of ordinary skill in the art that many more implementations and implementations are possible that are within the scope of the implementations. Although many possible combinations of features are shown in the accompanying figures and discussed in this detailed description, many other combinations of the disclosed features are possible. Any feature of any implementation may be used in combination with or substituted for any other feature or element in any other implementation unless specifically restricted. Therefore, it will be understood that any of the features shown and/or discussed in the present disclosure may be implemented together in any suitable combination. Accordingly, the implementations are not to be restricted except in light of the attached claims and their equivalents. Also, various modifications and changes may be made within the scope of the attached claims.

What is claimed is:

1. A multilayer metal-matrix composite, comprising:
at least two side sheets, including a first side sheet and a second side sheet; and
a metal core sheet, the metal core sheet being disposed between the first side sheet and the second side sheet,
wherein the metal core sheet is coated with an electroless coating selected from the group consisting of Nickel-Phosphorus electroless coating, Nickel-Boron electroless coating, and combinations thereof, and
wherein the metal core sheet is reinforced with a reinforcement material selected from the group consisting of Tungsten carbide, Aluminum oxide, polymeric reinforcements, and combinations thereof.

2. The multilayer metal matrix composite of claim 1, wherein the metal core sheet is selected from the group consisting of aluminum, iron, nickel, gold, copper, tin, titanium, cobalt, magnesium, platinum, palladium, zirconium, silver, beryllium, aluminum alloy, iron based alloy, magnesium alloy, platinum alloy, palladium alloy, zirconium alloy, steel, brass, silver alloy, beryllium alloy, super alloy, and combinations thereof.

3. The multilayer metal matrix composite of claim 1, wherein a material of the first side sheet is selected from the group consisting of aluminum, iron, nickel, gold, copper, tin, titanium, cobalt, magnesium, platinum, palladium, zirconium, silver, beryllium, aluminum alloy, iron based alloy, magnesium alloy, platinum alloy, palladium alloy, zirconium alloy, steel, brass, silver alloy, beryllium alloy, super alloy, and combinations thereof.

4. The multilayer metal matrix composite of claim 3, a material of the second side sheet is selected from the group consisting of aluminum, iron, nickel, gold, copper, tin, titanium, cobalt, magnesium, platinum, palladium, zirconium, silver, beryllium, aluminum alloy, iron based alloy, magnesium alloy, platinum alloy, palladium alloy, zirconium alloy, steel, brass, silver alloy, beryllium alloy, super alloy, and combinations thereof, and wherein the second side sheet includes a material that differs from the material of the first side sheet.

5. The multilayer metal matrix composite of claim 3, wherein the second side sheet includes a material that is substantially similar to the material of the first side sheet.

6. The multilayer metal matrix composite of claim 1, wherein a fracture toughness of the composite is greater than that of pure aluminum.

7. A method of fabricating a metal-matrix composite, the method comprising:
adding reinforcement particles to a metal core sheet to obtain a reinforced metal core sheet;
coating at least one side of the reinforced metal core sheet to obtain a coated metal core sheet;
heat-treating the coated metal core sheet;
placing the heat-treated coated metal core sheet between at least two side sheets to obtain a first initial composite; and
subjecting the first initial composite to an accumulative roll bonding process to obtain a metal-matrix composite sheet.

8. The method according to claim 7, wherein the metal core sheet is selected from the group consisting of aluminum, iron, nickel, gold, copper, tin, titanium, cobalt, magnesium, platinum, palladium, zirconium, silver, beryllium, an aluminum alloy, an iron based alloy, magnesium alloy, platinum alloy, palladium alloy, zirconium alloy, steel, brass, a silver alloy, a beryllium alloy, a super alloy, and combinations thereof.

9. The method according to claim 7, wherein the reinforcement particles are selected from the group consisting of ceramic reinforcements such as Tungsten carbide and Aluminum oxide, polymeric reinforcements such as PTFE, and combinations thereof.

10. The method according to claim 7, wherein the coating is selected from the group consisting of electroless coatings, such as Nickel-Phosphorus electroless coating, Nickel-Boron electroless coating and combinations thereof.

11. The method according to claim 7, wherein the side sheets are selected from the group consisting of aluminum, iron, nickel, gold, copper, tin, titanium, cobalt, magnesium, platinum, palladium, zirconium, silver, beryllium, an aluminum alloy, an iron based alloy, magnesium alloy, platinum alloy, palladium alloy, zirconium alloy, steel, brass, a silver alloy, a beryllium alloy, a super alloy, and combinations thereof.

12. The method according to claim 7, wherein the metal core sheet is coated using a physical vapor deposition (PVD) method, chemical vapor deposition (CVD) method, electroless coating method, and/or high velocity oxygen fuel thermal spray (HVOF) method.

13. The method of claim 7, wherein coating at least one side of the metal core sheet includes:
preparing the metal core sheet;
preparing an electroless bath; and
placing the metal core sheet in the electroless bath for a predetermined amount of time to perform an electroless coating process.

14. The method of claim 13, wherein preparing the metal core sheet includes:
annealing the metal core sheet;
cleaning the annealed metal core sheet with chemicals to remove extraneous materials from a surface of the metal core sheet; and
washing the cleaned and annealed metal core sheet to remove any chemicals adhering to the surface of the metal core sheet.

15. The method of claim 13, wherein preparing the electroless bath includes:
preparing an electroless solution;
adding reinforcement particles to the prepared electroless solution; and
adjusting the temperature of the electroless bath.

16. The method of claim 7, wherein the accumulative roll bonding process includes:
accumulative roll bonding the first initial composite;
dividing the accumulative roll bonded first initial composite into a plurality of pieces;
piling the pieces of the accumulative roll bonded first initial composite to obtain a second initial composite; and
repeating the three previous steps for a predetermined number of cycles to obtain a multilayer metal matrix composite.

17. The method of claim 7, wherein the reinforcement particles include Tungsten carbide particles with a particle size of approximately 4 microns.

18. The method of claim 7, wherein after the heat-treatment step, the morphology of the coated metal core sheet changes from amorphous to crystalline and a Ni₃P hard phase is formed.

19. The method of claim 16, wherein the metal-matrix composite sheet obtains metal characteristics after three cycles.

20. The method of claim 15, further comprising recharging the electroless bath by adding approximately 0.2 grams of solid Sodium-Borohydride per liter to the Nickel-Boron electroless bath approximately every 30 minutes, adding approximately 30 milliliters of an aqueous solution of 5 grams of Nickel Chloride per liter to the Nickel-Boron electroless bath approximately every hour, or adding approximately a solution of 10 milliliters per liter of Ethylenediamine to the Nickel-Boron electroless bath approximately every hour.
